(19) United States
(12) Patent Application Publication
(10) Pub. No.: US 2006/0145599 A1
(43) Pub. Date: Jul. 6, 2006

(54) OLEDs with phosphors

(76) Inventors: Reza Stegamat, Milpitas, CA (US); Homer Antoniadis, Mountain View, CA (US)

Correspondence Address: EPPING, HERMANN, FISCHER, Ridlerstrasse 55, Munich, 80339, DE

(21) Appl. No.: 11/028,881

(22) Filed: Jan. 4, 2005

(51) Int. Cl. H05B 33/00

(52) U.S. Cl. 313/504; 313/503

(57) ABSTRACT

An OLED application such as a light source is disclosed which has OLED elements utilizing an active EL (electro-luminescent) layer comprised of two elements, a host element emitting in a first spectrum and a dopant element emitting in a second spectrum different from the first. The OLED device also has a luminescent material disposed on the substrate or transparent electrode which converts the emission spectrum of light from the active EL layer.

### GOVERNMENT RIGHTS

This invention was made with Government support under Contract No. DE-FC26-04NT41947 awarded by the Department of Energy. The Government may have certain rights in the invention.

### BACKGROUND

Display and lighting systems based on LEDs (Light Emitting Diodes) have a variety of applications. Such display and lighting systems are designed by arranging a plurality of photo-electronic elements (“elements”) such as rows of individual LEDs. LEDs that are based upon semiconductor technology have traditionally used inorganic materials, but recently, the organic LED (“OLED”) has come into vogue. Examples of other elements/devices using organic materials include organic solar cells, organic transistors, organic detectors, and organic lasers.

An organic OLED is typically comprised of two or more thin organic layers (e.g., an electrically conducting organic layer and an emissive organic layer where the emissive organic layer emits light) which separate an anode and a cathode. Under an applied forward potential, the anode injects holes into the conducting layer, while the cathode injects electrons into the emissive layer. The injected holes and electrons each migrate (under the influence of an externally applied electric field) toward the oppositely charged electrode and produce an electro-luminescent emission upon recombination in the emissive layer. Similar device structure and device operation applies for OLEDs consisting of small molecule organic layers and/or polymeric organic layers. Each of the OLEDs can be a pixel element in a passive/active matrix OLED display or an element in a general area light source and the like. The construction of OLED light sources and OLED displays from individual OLED elements or devices is well known in the art. The displays and light sources may have one or more common layers such as common substrates, anodes or cathodes and one or more active/passive organic layers sandwiched in between to emit light in particular spectra. They may also consist of photo-resist or electrical separators, bus lines, charge transport and/or charge injection layers, and the like.

OLEDs typically emit light in a particular part of the visible spectrum (i.e. a particular color) such as blue, red or green. One issue has been the generation of white light from such OLEDs. The white light emitting organic materials are prepared by adding a small amount of red and green emitting materials to a blue light-emitting host. This approach, however, has proven tedious in that it requires careful control of the concentration of the components to acquire the desired white color. Further, the white light thus obtained has usually lower efficiency compared to that of the blue emitting host, thus requiring higher power consumption which is undesirable for lighting applications.

Alternatively, white emissive OLEDs have been proposed by the use of phosphor layers which are disposed on or coat the OLED. For instance, it has been proposed that a blue-emissive OLED be coated with red and green phosphors. Through down conversion, the blue light is partially absorbed by the red and green materials in the phosphor layer and partially transmitted. The absorbed light is converted to the red or and green emitting-lights, which in combination with the transmitted blue light form the three components of the white light. The white light emitted from these sources is more efficient than the original source (the blue-emissive OLED). This approach has been proposed by the GE Corporate Research group (Duggal, A. R., J. J. Shiang, et al. (2002). “Organic light-emitting devices for illumination quality white light.” Appl. Phys. Lett. 80(19): 3470-3472) and in U.S. Pat. No. 6,700,322. This approach has been used for both lighting applications and for display applications.

The stability of such devices, however, depends to a large extent on the stability of the blue emitting polymer host mentioned above. Currently most blue light emitting hosts, small molecule or polymeric have limited lifetime. Furthermore, the phosphor layer requires two components, namely green and red, in appropriate concentrations, particle size and absorption properties. Therefore, there is a need to design a new white emitting OLED.

### BRIEF DESCRIPTION OF THE DRAWINGS

FIG. 1 shows a cross-sectional view of an embodiment of an OLED device according to at least one embodiment of the invention.

FIG. 2 shows a cross-sectional view of an embodiment of an OLED device according to at least one embodiment of the invention.

### DETAILED DESCRIPTION

As used in describing the various embodiments of the invention, the term “luminescent material” includes any organic and/or inorganic substance, compound, element, or fabrication which produces/allows an emission of light not ascribable directly to incandescence such as phosphorescence and fluorescence or other luminous radiation resulting from chemical action, friction, solution, or the influence of light or of other radiation, and so on. Luminescent material includes, without limitation, anything which can be classified as photoluminescent, fluorescent or phosphorescent in nature. Examples of such “luminescent material” include color changing media (CCM), organic/inorganic phosphors, and can be in the form of dyes, powders, gels, laminates, pastes, etc.

In at least one embodiment of the invention, an OLED device is disclosed which utilizes 1) an active electro-luminescent (EL) layer composed from two spectrally distinct emitting elements, a host element capable of emitting in a first color and dopant element capable of emitting in a second, different color; and 2) at least one luminescent material capable of emitting in a third color different from the color of the host and dopant elements, disposed in the path of emission from the EL which modifies the spectral output (color) of the light emitted by the OLED device. In at least one embodiment of the invention, an OLED device is disclosed which includes an EL comprised of a blue-emitting host element and a red-emitting dopant element and a luminescent material comprising a yellow emitting material. In other exemplary embodiments of the invention, an OLED device is disclosed which includes an EL comprised of a blue-emitting host element and a red-emitting dopant element and a luminescent material comprising a green emitting material. The result of such embodiments is a white spectral light output from the OLED device. The luminescent material, as described above can be at least one of a polymer, monomer, co-polymer, polymer blend, small molecule, organic phosphor or inorganic phosphor, color filter, CCM, and so on.

In at least one embodiment of the invention, the EL layer is composed of at least two light emitting polymers (LEPs) such as a blue-emitting LEP and a red-emitting LEP. Advantageously, OLED devices with multiple spectra EL layers and phosphorescent material disposed in the path of the light emission can offer better lifetime stability and can achieve accurate device output color at high Color Rendering Indices (CRIs). The accuracy of the color can be measured by a color coordinate system such as the well-known CIE (Commission International de I'Eclairage) coordinate system using x and y coordinates to represent colors. The CRI is a measure of the degree of distortion in the apparent colors when measured with the output light source as opposed to a standard light source such as a blackbody. The CRI is defined such that a blackbody source has a CRI of 100, with all other light sources having lower values.

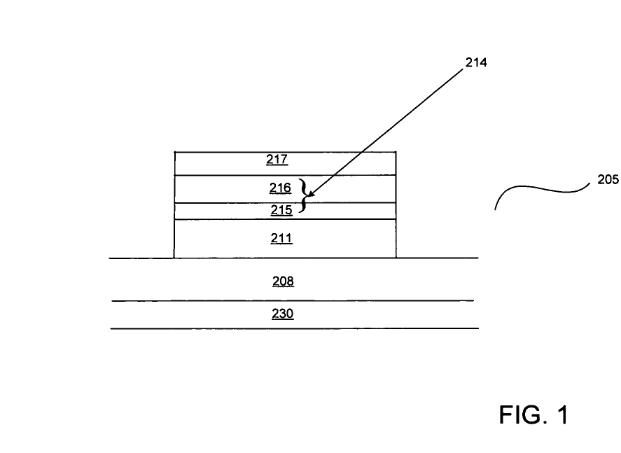

FIG. 1 shows a cross-sectional view of an embodiment of an OLED device 205 according to at least one embodiment of the invention. The OLED device 205 includes a substrate 208 and a first electrode 211 on the substrate 208. The first electrode 211 may be patterned for pixilated applications or unpatterned for backlight applications. The OLED device 205 also includes a semiconductor stack 214 on the first electrode 211. The semiconductor stack 214 includes at least the following: (1) conducting polymer layer 215 and (2) an active electro-luminescent (“EL”) layer 216. In accordance with at least one embodiment of the invention, the active EL layer 216 is composed of a host element capable of emitting light in a first color (spectrum) and a dopant element capable of emitting light in a second color (spectrum) different from the first color.

If the first electrode 211 is an anode, then the conducting polymer layer 215 is on the first electrode 211, and the active EL layer 216 is on the conducting polymer layer 215. Alternatively, if the first electrode 211 is a cathode, then the active EL layer 216 is on the first electrode 211, and the conducting polymer layer 215 is on the active EL layer 216.

The OLED device 205 also includes a second electrode 217 on the semiconductor stack 214. Other layers than that shown in FIG. 1 may also be added such as insulating layers, barrier layers, electron/hole injection and blocking layers, getter layers, and so on. In accordance with the invention, a luminescent material 230 is disposed in the path of light emission from the active EL layer 216. If the OLED device 205 is a bottom-emitting OLED device, then the phosphorescent material 230 is disposed on the substrate 208. If the OLED device 205 is a top-emitting OLED device, then the phosphorescent material 230 is disposed on the first electrode 211. Exemplary embodiments of these layers are described in greater detail below.

Substrate 208:

The substrate 208 can be any material, which can support the additional layers and electrodes, and is transparent or semi-transparent to the wavelength of light generated in the device. Alternatively, the substrate 208 can be opaque (when used in top-emitting devices). Preferable substrate materials include glass, quartz, silicon, and plastic, preferably, thin, flexible glass. The preferred thickness of the substrate 208 depends on the material used and on the application of the device. The substrate 208 can be in the form of a sheet or continuous film. The continuous film is used, for example, for roll-to-roll manufacturing processes which are particularly suited for plastic, metal, and metallized plastic foils.

First Electrode 211:

In one configuration, the first electrode 211 functions as an anode (the anode is a conductive layer which serves as a hole-injecting layer). Typical anode materials include metals (such as platinum, gold, palladium, indium, and the like); metal oxides (such as lead oxide, tin oxide, indium-tin oxide, and the like); graphite; doped inorganic semiconductors (such as silicon, germanium, gallium arsenide, and the like); and doped conducting polymers (such as polyaniline, polypyrrole, polythiophene, and the like).

In an alternative configuration, the first electrode 211 functions as a cathode (the cathode is a conductive layer which serves as an electron-injecting layer and which comprises a material with a low work function). The cathode, rather than the anode, is deposited on the substrate 208 in the case of, for example, a top-emitting OLED. Top emitting OLEDs can also have anodes in the opaque substrate and the cathode consists of transparent low work function materials. Typical cathode materials are listed below in the section for the “second electrode 217”.

The first electrode 211 can be transparent, semi-transparent, or opaque to the wavelength of light generated within the device. Preferably, the thickness of the first electrode 211 is from about 10 nanometers (“nm”) to about 1000 nm, more preferably from about 50 nm to about 200 nm, and most preferably is about 100 nm.

The first electrode layer 211 can typically be fabricated using any of the techniques known in the art for deposition of thin films, including, for example, vacuum evaporation, sputtering, electron beam deposition, or chemical vapor deposition, using for example, pure metals or alloys, or other film precursors.

Conducting Polymer Layer 215:

The conducting polymer layer 215 can be formed from a solution that is comprised of water, polyethylenedioxythiophene (“PEDOT”), and polystyrenesulfonic acid (“PSS”), and wherein the weight ratio of PSS to PEDOT can be from 1 to 20. Preferably, the ratio of the PEDOT to the PSS is one part by weight of the PEDOT to twenty parts by weight of the PSS. The range of thickness of each of the regions is typically from about 10 nm to about 500 nm; and preferably, from about 30 nm to about 200 nm.

Active EL Layer 216:

The active EL layer 216 is comprised of an organic electroluminescent material which emits light upon application of a potential across first electrode 211 and second electrode 217. Examples of such organic electroluminescent materials include:

(i) poly(p-phenylene vinylene) and its derivatives substituted at various positions on the phenylene moiety;

(ii) poly(p-phenylene vinylene) and its derivatives substituted at various positions on the vinylene moiety;

(iii) poly(p-phenylene vinylene) and its derivatives substituted at various positions on the phenylene moiety and also substituted at various positions on the vinylene moiety; (iv) poly(arylene vinylene), where the arylene may be such moieties as naphthalene, anthracene, furylene, thienylene, oxadiazole, and the like;

(v) derivatives of poly(arylene vinylene), where the arylene may be as in (iv) above, and additionally have substituents at various positions on the arylene;

(vi) derivatives of poly(arylene vinylene), where the arylene may be as in (iv) above, and additionally have substituents at various positions on the vinylene;

(vii) derivatives of poly(arylene vinylene), where the arylene may be as in (iv) above, and additionally have substituents at various positions on the arylene and substituents at various positions on the vinylene;

(viii) co-polymers of arylene vinylene oligomers, such as those in (iv), (v), (vi), and (vii) with non-conjugated oligomers; and

(ix) polyp-phenylene and its derivatives substituted at various positions on the phenylene moiety, including ladder polymer derivatives such as poly(9,9-dialkyl fluorene) and the like;

(x) poly(arylenes) where the arylene may be such moieties as naphthalene, anthracene, furylene, thienylene, oxadiazole, and the like; and their derivatives substituted at various positions on the arylene moiety;

(xi) co-polymers of oligoarylenes such as those in (x) with non-conjugated oligomers;

(xii) polyquinoline and its derivatives;

(xiii) co-polymers of polyquinoline with p-phenylene substituted on the * phenylene with, for example, alkyl or alkoxy groups to provide solubility; and

(xiv) rigid rod polymers such as poly(p-phenylene-2,6-benzobisthiazole), poly(p-phenylene-2,6-benzobisoxazole), polyp-phenylene-2,6-benzimidazole), and their derivatives.

Other organic emissive polymers such as those utilizing polyfluorene include that emit green, red, blue, or white light or their families, copolymers, derivatives, or mixtures thereof. Other polymers include polyspirofluorene-like polymers available from Covion Organic Semiconductors GmbH, Frankfurt, Germany.

Alternatively, rather than polymers, small organic molecules that emit by fluorescence or by phosphorescence can serve as the organic electroluminescent layer. Examples of small-molecule organic electroluminescent materials include: (i) tris(8-hydroxyquinolinato) aluminum (Alq); (ii) 1,3-bis(N,N-dimethylaminophenyl)-1,3,4-oxidazole (OXD-8); (iii) -oxo-bis(2-methyl-8-quinolinato)aluminum; (iv) bis(2-methyl-8-hydroxyquinolinato) aluminum; (v) bis(hydroxybenzoquinolinato) beryllium (BeQ.sub.2); (vi) bis(diphenylvinyl)biphenylene (DPVBI); and (vii) arylamine-substituted distyrylarylene (DSA amine). Such polymer and small-molecule materials are well known in the art and are described in, for example, U.S. Pat. No. 5,047,687 issued to VanSlyke.

The thickness of the active EL layer 216 is from about 5 nm to about 500 nm, preferably, from about 20 nm to about 100 nm, and more preferably is about 75 nm. The active EL layer 216 can be a continuous film that is non-selectively deposited (e.g. spin-coating) or discontinuous regions that are selectively deposited (e.g. by ink-jet printing)

In accordance with the invention, the active EL layer 216 is composed of at least two light emitting elements chosen, for example, from those listed above. In the case of two light-emitting elements, the relative concentration of the host element and the dopant element can be adjusted to obtain the desired color. The active EL layer 216 can be fabricated by blending or mixing the elements, either physically, chemically, or both. In one embodiment of the invention, the active EL layer is composed of a blue-emitting LEP host element and a red-emitting LEP dopant element. For instance, a polymer matrix consisting of blue-emitting polymers with red-emitting side chains or groups can be utilized in fabricating the LEP. Other exemplary embodiments would include an active EL layer with blue-emitting host and green-emitting dopant elements. In general, the host element is a blue emitting material and the dopant can be an element emitting a primary color other than blue.

The dopant element within the active EL layer 216 may be infrared or near infrared so as not to affect the visible output of the device 205. The dopant element concentration and/or photo-efficiency can be selected to produce particular desired output spectra. For instance, if a more “pinkish” white is desired, the concentration of a red-emitting dopant can be increased or a red-emitting dopant material can be selected which has a higher photo-efficiency. The dopant element can thus play a role in stabilizing the lifetime of the output of the device 205 as well as in adjusting the color of emission of the device 205. In the case of a blue-emitting host element and a red-emitting dopant, for instance, it has been demonstrated that the addition of the red-emitting dopant improves the overall lifetime of the device (the desired spectral output remains stable for a longer lifetime).

Second Electrode 217:

In one configuration, the second electrode layer 217 functions as a cathode (the cathode is a conductive layer which serves as an electron-injecting layer and which comprises a material with a low work function). While the cathode can be comprised of many different materials, preferable materials include aluminum, silver, magnesium, calcium, barium, or combinations thereof. More preferably, the cathode is comprised of aluminum, aluminum alloys, or combinations of magnesium and silver. Additional cathode materials may contain fluorides such as LiF and the like.

In an alternative configuration, the second electrode layer 217 functions as an anode (the anode is a conductive layer which serves as a hole-injecting layer and which comprises a material with work function greater than about 4.5 eV). The anode, rather than the cathode, is deposited on the semiconductor stack 214 in the case of, for example, a top-emitting OLED. Typical anode materials are listed earlier in the section for the “first electrode 211”. Top emitting OLEDs can have cathodes as the transparent electrode and in this case cathode is deposited after the emissive layers.

The thickness of the second electrode 217 is from about 10 nm to about 1000 nm, preferably from about 50 nm to about 500 nm, and more preferably, from about 100 nm to about 300 nm. While many methods are known to those of ordinary skill in the art by which the second electrode 217 may be deposited, vacuum deposition and sputtering methods are preferred.

Luminescent Material 230

If OLED device 205 is a bottom-emitting OLED, the light emitted from the active EL layer 217 passes through the substrate 208. In accordance with various embodiments of the invention, a luminescent material 230 is disposed on the exposed side of the substrate 208 to shift the color or spectra of light emitted by the active EL layer 217. Particularly, in the embodiment of a blue-emitting host and red-emitting dopant in the active EL layer 217, a yellow-emitting luminescent material 230 can be utilized to create a white output emission from the OLED device 205. In alternative embodiments of the invention, in the embodiment of a blue-emitting host and red-emitting dopant in the active EL layer 217, a green luminescent material 230 can be utilized to create a white output emission from the OLED device 205.

Luminescent material 230 may consist of includes any organic and/or inorganic substance, compound, element, fabrication or device which produces/allows an emission of light not ascribable directly to incandescence such as phosphorescence and fluorescence or other luminous radiation resulting from vital processes, chemical action, friction, solution, or the influence of light or of ultraviolet or cathode rays, etc. Luminescent material includes, without limitation, anything which can be classified as photoluminescent, fluorescent or phosphorescent in nature. Examples of such “luminescent material” include color filters, color changing media (CCM), organic/inorganic phosphors, and can be in the form of dyes, powders, gels, laminates, pastes, etc. Exemplary phosphor materials are discussed in U.S. Pat. No. 6,700,322. In accordance with at least some embodiments of the present invention, the emitted color of the luminescent material 230 is different from the colors emitted from the elements of the active EL layer 217, but is a complementary color to those generated by 217 to produce a white light. For example, if the active EL layer 217 consists a blue emitting host doped with a red emitting material, the emitting color of the luminescent material 230 could be green or yellow or orange. Or alternatively if the active EL layer 217 consists a blue emitting host doped with a green or yellow emitting material, the emitting color of the luminescent material 230 could be red or orange.

Also, in accordance with the present invention, the white-light emitting device consists of an active EL layer 217, which further includes at least one host element and one dopant element, and a luminescent material coated on the emitting side of the device, and wherein the energy gap of the host element is higher than the energy gap of dopant element and the energy gap of the luminescent material 230. The energy gap is the difference between the Highest Occupied Molecular Orbital (HOMO) and Lowest Unoccupied Molecular Orbital (LUMO) and is also referred to as band gap. For example, in one embodiment of the present invention, the host element is a blue-light emitting polymer with an energy gap of more than 2.9 eV, and the dopant material is a red-emitting polymer with an energy gap of about 2 eV, and the luminescent material is a green or yellow-green emitting phosphor with an energy gap of about 2.5 eV.

Luminescent material 217 may also include one or more layers of nanocrystals and/or quantum dots such as CdSe(ZnS). This material is described in a publication entitled “Electroluminescence from single monolayers of nanocrystals in molecular organic devices,” Nature, Vol. 420, pp. 800-803 (December 2002).

The luminescent material 230 can be in the form of particles, powders, films, pastes, emulsions, dyes, coatings, or separable layers. The luminescent material 230 can be deposited or formed directly on substrate 208 or be separately prepared and attached onto substrate 208 by adhesives and/or curing. Further, the luminescent material 230 can be incorporated into a cross-linkable material which can then be chemically bonded to the substrate 208. Additionally, the luminescent material can be dispersed in a polymeric matrix such as a polycarbonate and the like, wherein the final dispersion can be coated by various techniques onto the substrate 208.

The addition of a suitable dopant element within active EL layer 216 reduces or eliminates the requirements on the luminescent material 230 to produce an additional spectral component to the overall output of device 205. For instance, the introduction of a red-emitting dopant eliminates the need for a red-emitting luminescent material (in addition to the yellow-emitting or orange-emitting luminescent material) in order to produce white output. In embodiments where the OLED is “top-emitting” as discussed above, the electrode (cathode 217) may be made transparent or translucent to allow light to pass from the active EL layer 217. In such cases, the luminescent material 230 would be attached, bonded or cured to the cathode 217 rather than the substrate 208 as with a bottom-emitting OLED.

The luminescent material may also act to diffuse the light originating from the active EL layer. Diffusion can be achieved for instance when the luminescent material is a laminate which is attached to the substrate or transparent cathode. Certain powders and crystals may also provide light diffusion. Light diffusion may be useful in light source applications where a spreading of light, rather than distinct projections is preferable.

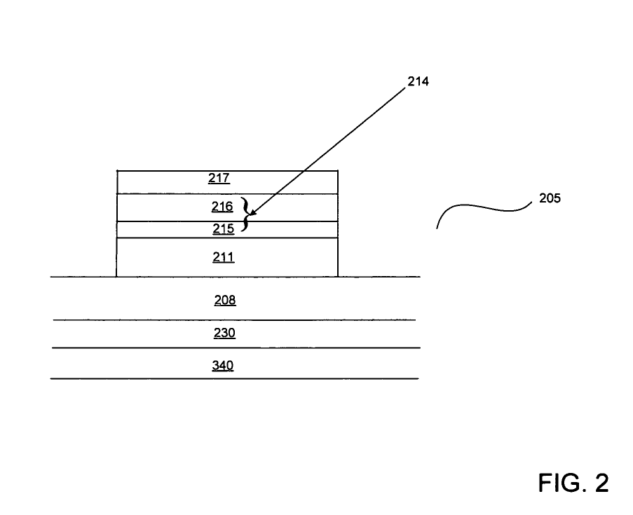

FIG. 2 shows a cross-sectional view of an embodiment of an OLED device 206 according to at least one embodiment of the invention. The layers, electrodes and materials in OLED device 206 which are like-numbered with those of OLED device 205 are similar in form, composition and function thereto. Additionally, OLED device 206 is equipped with a barrier layer 340 which protects the luminescent material 230 from environmental, physical and chemical damage or degradation. Exemplary materials for barrier layer are illustrated in pending U.S. patent application Ser. No. 10/242,656, entitled “Active Electronic Devices” filed on Sep. 11, 2002, the disclosure of which is—incorporated by reference herein. Other examples of such barrier layers include but are not limited to any moisture or oxygen preventing transparent barrier, any flexible or rigid barrier which may or may not contain getter materials, metal oxides or nitrides deposited for example by vacuum evaporation, sputtering or other techniques. Other embodiments and modifications of the present invention may occur to those skilled in the art subsequent to a review of the information presented herein; these embodiments and modifications, as well as equivalents thereof, are also included within the scope of this invention.

The OLED lighting sources and displays produced from a combination or arrays of OLED devices described earlier can be used within applications such as information displays in vehicles, industrial and area lighting, telephones, printers, and illuminated signs.

As any person of ordinary skill in the art of light-emitting device fabrication will recognize from the description, figures, and examples that modifications and changes can be made to the embodiments of the invention without departing from the scope of the invention defined by the following claims.

What is claimed:

1. A device capable of emitting light in an output spectrum, comprising:
an active electro-luminescent (EL) layer composed of at least one host element emitting light in a first spectrum and a dopant element emitting light in a second spectrum different from said first spectrum;
a transparent layer capable of at least partially transmitting light emitted by said active EL layer; and
a luminescent material disposed in order to convert the spectrum of light emitted by the active EL layer and transmitted through said transparent layer, said luminescent material yielding said output spectrum.

2. The device of claim 1 wherein said output spectrum is white.

3. The device of claim 1 wherein said luminescent material is at least one of a phosphorescent and fluorescent material.

4. The device of claim 1 wherein said host element and said dopant element is at least one of a polymer, polymer blend, polymer matrix, copolymer, small molecule, monomer and doped small molecule.

5. The device of claim 1 wherein said luminescent material is at least one of an organic and inorganic material.

6. The device of claim 2 wherein said luminescent material is at least one of a green-emitting material, orange-emitting material and yellow-emitting material.

7. The device of claim 1 wherein said first spectrum is blue and said second spectrum is at least one of red, orange and yellow.

8. The device of claim 1 wherein said luminescent material is at least one of a powder, paste, gel, laminate, emulsion, dye, coating, organic layer and inorganic layer.

9. The device of claim 1 wherein said luminescent material is capable of emitting in a spectrum different from both the first spectrum and the second spectrum.

10. The device of claim 1 further comprising:
a barrier layer incorporated to protect said luminescent material from environmental exposure.

11. The device of claim 1 further comprising:
an anode layer; and
a cathode layer, wherein said active EL layer is disposed between said anode layer and said cathode layer.

12. The device of claim 11 further comprising:
at least one organic layer in addition to said active EL layer, said at least organic layer disposed between said anode layer and said cathode layer.

13. The device of claim 1 wherein said luminescent material acts to diffuse light from said active EL layer.

14. The device of claim 1 wherein said luminescent material is attached physically and/or chemically to said transparent layer.

15. The device of claim 14 wherein said luminescent material is laminated onto said transparent layer, said luminescent material acting to diffuse light from said active EL layer.

16. The device of claim 12 wherein said organic layer may include at least one of a charge transport layer and a charge injection layer.

17. The device of claim 1 wherein said device is part of light source application.

18. The device of claim 1 wherein said luminescent material is composed of at least one of Yttrium, Cerium and Aluminum.

19. The device of claim 1 wherein the host element has an energy band gap larger than the energy band gap of the dopant element and the energy band gap of the luminescent material.

20. The device of claim 1 wherein said transparent layer is a substrate.

21. The device of claim 1 wherein said transparent layer is a cathode layer.

22. The device of claim 1 wherein said luminescent material is at least one of a quantum dots structure and nanocrystal.
